(19) United States
(12) Patent Application Publication
(10) Pub. No.: US 2026/0354057 A1
(43) Pub. Date: Nov. 5, 2026

(54) METHODS FOR SURFACE PASSIVATION OF III-V SEMICONDUCTORS

(71) Applicant: Tokyo Electron Limited, Tokyo (JP)

(72) Inventor: Kate Abel, Austin, TX (US)

(21) Appl. No.: 19/194,352

(22) Filed: Apr. 30, 2025

(51) Int. Cl. H10P 14/60; C23C 22/02; C23C 22/73; C23C 22/78; H10P 14/692; H10P 70/00

(52) U.S. Cl. CPC H10P 14/6324; C23C 22/02; C23C 22/73; C23C 22/78; H10P 14/6939; H10P 70/10

(57) ABSTRACT

Embodiments of methods are provided for passivating an exposed surface of a semiconductor material (e.g., a III-V semiconductor material) formed on or within a substrate. In the disclosed embodiments, the semiconductor material is passivated by exposing the substrate to a chemical solution comprising an electrophilic fluorinating agent, which reacts with an exposed surface of the semiconductor material to form a fluorinated passivation layer on the exposed surface in a relatively fast, quasi-self-limiting manner. In some embodiments, a photosensitive dye is added to the chemical solution and the substrate is illuminated, while exposed to the chemical solution, to further improve the surface passivation rate.

### TECHNICAL FIELD

The present disclosure relates to the processing of semiconductor substrates. In particular, it provides improved systems and methods for forming passivation layers on a substrate surface comprising a III-V semiconductor material.

### BACKGROUND

Semiconductor devices require careful surface passivation. Silicon became the dominant semiconductor material because its oxide is easy to form, robust, and a good passivation layer. The formation of an oxide passivation layer on silicon is self-limiting, preserves the semiconducting properties of the underlying silicon, provides electrical insulation, and does not create trap states.

Other classes of material, such as III-V semiconductors, have semiconducting properties that are superior to silicon, but are much less widely used because they are difficult to passivate. Oxides formed on III-V semiconductors tend to be poor passivation layers based on the lack of self-limiting behavior, and the creation of charge trap and recombination centers at the surface. As such, other chemical processes, such as cladding (e.g., with zinc sulfide (ZnS) and/or zinc selenide (ZnSe) shells) and surface passivation (using, e.g., hydrofluoric acid (HF) based chemistries), have been used as passivation methods for III-V semiconductors.

However, the currently known passivation methods for III-V semiconductors are too slow, and thus, not compatible with high-volume manufacturing (HVM). Accordingly, it would be desirable to provide new, HVM-compatible passivation methods for III-V semiconductors.

### SUMMARY

The present disclosure provides various embodiments of methods for processing a semiconductor substrate. More specifically, the present disclosure provides various embodiments of methods that can be used to passivate an exposed surface of a semiconductor material (e.g., a III-V semiconductor material) formed on or within a semiconductor substrate. In the disclosed embodiments, a semiconductor material is passivated by exposing the substrate to a chemical solution comprising an electrophilic fluorinating agent, which reacts with an exposed surface of the semiconductor material to form a fluorinated passivation layer on the exposed surface of the semiconductor material in a relatively fast, quasi-self-limiting manner. In some embodiments, a photosensitive dye may be added to the chemical solution and the substrate may be illuminated, while exposed to the chemical solution, to further improve the surface passivation rate.

According to one embodiment, a method is provided herein to process a semiconductor substrate. In general, the method may include: (a) providing the substrate, the substrate comprising a III-V semiconductor material; and (b) exposing the substrate to a non-aqueous chemical solution comprising an electrophilic fluorinating agent dissolved in a non-aqueous solvent. When the substrate is exposed to the non-aqueous chemical solution, the electrophilic fluorinating agent reacts with an exposed surface of the III-V semiconductor material to form a fluorinated passivation layer on the exposed surface of the III-V semiconductor material. In some embodiments, the method may further include cleaning the exposed surface of the III-V semiconductor material prior to exposing the substrate to the non-aqueous chemical solution. If a cleaning step is performed, the cleaning step may remove contaminants from the exposed surface of the III-V semiconductor material before the fluorinated passivation layer is formed on the exposed surface.

A wide variety of electrophilic fluorinating agents and non-aqueous solvents may be included within the non-aqueous chemical solution disclosed herein. Examples of electrophilic fluorinating agents include, but are not limited to, Selectfluor™ (1-chloromethyl-4-fluoro-1,4-diazoniabicyclo[2.2.2]octane bis(tetrafluoroborate)), 1-fluoropyridinium triflate, 1-fluoro-2,4,6-trimethylpyridinium tetrafluoroborate, N-fluorobenzenesulfonimide, fluoroxytrifluoromethane, perchloryl fluoride, xenon difluoride and N-fluorobis[(trifluoromethyl)sulfonyl]imide. The non-aqueous solvent may be an ether, a ketone, a halocarbon, a heterocyclic, an alcohol or another polar organic solvent or chlorocarbon solvent. In one example embodiment, the non-aqueous chemical solution may comprise Selectfluor™ dissolved in acetonitrile.

In some embodiments, the non-aqueous chemical solution may further include a photosensitive dye, and the method may further include exposing the substrate to illumination while the substrate is exposed to the non-aqueous chemical solution. When a photosensitive dye is added to the chemical solution and the substrate is exposed to illumination, the photosensitive dye may absorb the illumination, transition to a higher energy state and transfer energy to the electrophilic fluorinating agent contained within the chemical solution to photoactivate the electrophilic fluorinating agent and increase a rate at which the fluorinated passivation layer is formed on the exposed surface of the III-V semiconductor material.

A wide variety of photosensitive dyes may be added to the chemical solution to photoactivate the electrophilic fluorinating agent. For example, the photosensitive dye may be a thiazine dye (such as, e.g., methylene blue (C₁₆H₁₈ClN₃S)), a fluorescein dye (such as, e.g., Rose Bengal (4,5,6,7-tetrachloro-2′,4′,5′,7′-tetraiodofluorescein)), a porphyrin dye (such as, e.g., porphyrin, substituted porphyrin, and porphyrin-metal complexes), an eosin dye, a rhodamine dye, a ruthenium dye or another metal bipyridine. In some embodiments, the method may further include selecting the photosensitive dye for use within the non-aqueous chemical solution prior to exposing the substrate to the non-aqueous chemical solution. The photosensitive dye selected for use is one that is chemically stable within the non-aqueous chemical solution. In one example embodiment, the non-aqueous chemical solution may comprise Selectfluor™ and methylene blue (C₁₆H₁₈ClN₃S) dissolved in acetonitrile.

In some embodiments, the III-V semiconductor material may be indium phosphide (InP) having an InP surface. Unlike conventional InP surface passivation methods, which utilize aqueous hydrofluoric acid (HF) solution to passivate InP surfaces, the method disclosed herein exposes the InP surface to a non-aqueous chemical solution that does not contain HF. Instead, the method disclosed above exposes the InP surface to a non-aqueous chemical solution comprising an electrophilic fluorinating agent dissolved in a non-aqueous solvent. When the substrate is exposed to a non-aqueous chemical solution as described herein, the electrophilic fluorinating agent reacts with the InP surface to form an indium fluoride (InFₓ) passivation layer on the InP surface. The rate of fluorination (or the surface passivation rate) of the InP surface is significantly faster (e.g., at least an order of magnitude faster) than conventional HF-mediated surface passivation techniques. In some embodiments, a photosensitive dye may be added to the non-aqueous chemical solution and the substrate may be illuminated to photoactivate the electrophilic fluorinating agent and further increase the fluorination rate, for example, by another order of magnitude.

According to another embodiment, another method is provided herein to process a semiconductor substrate. In general, the method may include: (a) providing the substrate, the substrate comprising a semiconductor material containing a phosphide, an arsenide or an antimonide; (b) exposing the substrate to a chemical solution comprising an electrophilic fluorinating agent and a photosensitive dye dissolved in a solvent, wherein the electrophilic fluorinating agent reacts with an exposed surface of the semiconductor material to form a fluorinated passivation layer on the exposed surface of the semiconductor material; and (c) exposing the substrate to illumination while the substrate is exposed to the chemical solution, wherein the photosensitive dye absorbs the illumination, transitions to a higher energy state and transfers energy to the electrophilic fluorinating agent to photoactivate the electrophilic fluorinating agent and increase a rate at which the fluorinated passivation layer is formed on the exposed surface of the semiconductor material. In some embodiments, the method may further include cleaning the exposed surface of the semiconductor material prior to exposing the substrate to the chemical solution to remove contaminants from the exposed surface of the semiconductor material.

The semiconductor material may contain a wide variety of phosphides, arsenides or antimonides. For example, the semiconductor material may be indium phosphide (InP), aluminum phosphide (AlP), gallium phosphide (GaP), aluminum gallium phosphide (AlGaP), gallium indium phosphide (GaInP), aluminum indium phosphide (AlInP), aluminum gallium indium phosphide (AlGaInP), gallium arsenide (GaAs), indium arsenide (InAs), aluminum arsenide (AlAs), indium gallium arsenide (InGaAs), aluminum gallium arsenide (AlGaAs), aluminum indium arsenide (AlInAs), indium antimonide (InSb), aluminum antimonide (AlSb), gallium antimonide (GaSb), indium gallium aluminum antimonide (InGaAlSb), indium gallium antimonide (InGaSb), indium aluminum antimonide (InAlSb), or gallium aluminum antimonide (GaAlSb). In one example embodiment, the semiconductor material may be indium phosphide (InP) having an InP surface, and the electrophilic fluorinating agent may react with the InP surface to form an indium fluoride (InFₓ) passivation layer on the InP surface.

In the method disclosed herein, the chemical solution does not contain hydrofluoric acid (HF). Instead, the chemical solution includes an electrophilic fluorinating agent and a photosensitive dye dissolved in a solvent. A wide variety of electrophilic fluorinating agents, photosensitive dyes and solvents may be included within the chemical solution. For example, the electrophilic fluorinating agent may be Selectfluor™ (1-chloromethyl-4-fluoro-1,4-diazoniabicyclo[2.2.2]octane bis(tetrafluoroborate)), 1-fluoropyridinium triflate, 1-fluoro-2,4,6-trimethylpyridinium tetrafluoroborate, N-fluorobenzenesulfonimide, fluoroxytrifluoromethane, perchloryl fluoride, xenon difluoride or N-fluorobis[(trifluoromethyl)sulfonyl]imide. The photosensitive dye may be a thiazine dye, a fluorescein dye, a porphyrin dye, an eosin dye, a rhodamine dye, a ruthenium dye or another metal bipyridine. The solvent may be an aqueous solvent (water) or a non-aqueous solvent (e.g., an ether, a ketone, a halocarbon, a heterocyclic, an alcohol or another polar organic solvent or chlorocarbon solvent).

In some embodiments, Selectfluor™ may be used as the electrophilic fluorinating agent and the solvent may be water, acetonitrile, ethyl acetate, acetone, dimethyl sulfoxide (DMSO), furan, dimethylformamide, methanol, diethyl ether, isopropyl alcohol, dioxane or toluene. In one example embodiment, the chemical solution may comprise Selectfluor™ and methylene blue (C₁₆H₁₈ClN₃S) dissolved in acetonitrile.

As noted above and described further herein, the present disclosure provides various embodiments of methods for passivating surfaces of III-V semiconductor materials. Of course, the order of discussion of the different steps as described herein has been presented for the sake of clarity. In general, these steps can be performed in any suitable order. Additionally, although each of the different features, techniques, configurations, etc., herein may be discussed in different places of this disclosure, it is intended that each of the concepts can be executed independently of each other or in combination with each other. Accordingly, the present invention can be embodied and viewed in many different ways.

Note that this Summary section does not specify every embodiment and/or incrementally novel aspect of the present disclosure or claimed inventions. Instead, the summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 is a flowchart diagram illustrating one embodiment of a method that utilizes the techniques described herein to passivate an exposed surface of a III-V semiconductor material.

FIG. 2 is a block diagram illustrating one embodiment of a process flow that utilizes the techniques described herein to passivate an exposed surface of a III-V semiconductor material.

FIG. 3 is a graph of X-ray photoelectron spectroscopy (XPS) data illustrating the indium (In) 3d spectra of indium phosphide (InP) coupons as received, after cleaning, and after fluorination using the various fluorination techniques disclosed herein.

FIG. 4 is a graph of XPS data illustrating the fluorine (F) 1s spectra of InP coupons as received, after cleaning, and after fluorination using the various fluorination techniques disclosed herein.

FIGS. 5A-5B are graphs of the deconvolution of the In 3d_{5/2} peak after 10 minutes and 60 minutes of fluorination using the dark fluorination process disclosed herein, illustrating a lower binding energy peak consistent with InP and a higher binding energy peak consistent with indium fluoride (InFₓ).

FIG. 6 is a graph depicting the fractional integrated area in the higher binding energy peak as a function of fluorination time (expressed in minutes) as a metric for extent of fluorination achieved in dark fluorination process disclosed herein.

FIGS. 7A-7D are graphs of the deconvolution of the In 3d_{5/2} peak after 1 minute, 5 minutes, 10 minutes and 25 minutes of fluorination with the photoactivated fluorination process disclosed herein, illustrating a lower binding energy peak consistent with InP and a higher binding energy peak consistent with indium fluoride (InFₓ).

FIG. 8 is a graph depicting the fractional integrated area in the higher binding energy peak as a function of fluorination time (expressed in minutes) as a metric for extent of fluorination achieved in the photoactivated fluorination process disclosed herein.

FIG. 9 is a flowchart diagram illustrating another embodiment of a method that utilizes the techniques described herein to passivate a surface of a semiconductor material.

### DETAILED DESCRIPTION

Embodiments of methods are provided herein for processing a substrate. More specifically, embodiments of methods are provided for passivating an exposed surface of a semiconductor material (e.g., a III-V semiconductor material) formed on or within a substrate. In the disclosed embodiments, the semiconductor material is passivated by exposing the substrate to a chemical solution comprising an electrophilic fluorinating agent, which reacts with an exposed surface of the semiconductor material to form a fluorinated passivation layer on the exposed surface in a relatively fast, quasi-self-limiting manner. In some embodiments, a photosensitive dye is added to the chemical solution and the substrate is illuminated, while exposed to the chemical solution, to further improve the surface passivation rate.

III-V semiconductors are compounds formed by combining elements from Group III (e.g., boron (B), aluminum (Al), gallium (Ga), indium (In), etc.) and Group V (e.g., nitrogen (N), phosphorus (P), arsenic (As), antimony (Sb), etc.) of the periodic table. Unlike silicon, which has an indirect bandgap, III-V semiconductor materials have a direct bandgap and high electron mobility, making them particularly suitable in specialty semiconductors and optoelectronics. For example, III-V semiconductor materials containing phosphides (such as, for example, indium phosphide, InP) are used in the production of light emitting diodes (LEDs) for display technologies. As pixel density increases to increase resolution and transition to micro LEDs (μLEDs), the efficiency of these devices decreases. This leads to problems with power consumption and heat generation required to achieve a target brightness.

Deposition of InP films has been optimized to the point where defect-free, epitaxial-quality films are possible. The problems for building μLED devices come during the subsequent etch steps. Surface damage during the anisotropic etch used to define individual pixels of the LED array (referred to as the mesa etch) leads to surface defects, which act as recombination centers. As devices shrink, surface-area-to-volume ratios increase and surface quality limits device performance. Technologies to passivate these etch-generated defects are, therefore, critical for the production of high-performance devices.

Surface passivation of InP films has previously been accomplished through epitaxial coatings (such as zinc sulfide (ZnS) and/or zinc selenide (ZnSe) shells) and through various surface passivation treatments. However, adding a semiconducting material (such as ZnS or ZnSe) to the InP surface is not ideal for many device integrations, so surface passivation treatments are generally used to passivate surface defect sites on InP films. A fluorination process that relies on photoelectrochemistry has been used to passivate InP surfaces using non-aqueous solutions of hydrofluoric acid (HF). During this known fluorination process, the InP surface is illuminated with photon energies greater than the bandgap while the InP surface is exposed to a non-aqueous HF solution. A small number of photogenerated electron/hole pairs make it to the InP surface where they drive redox reactions between the reactants present within the non-aqueous HF solution (e.g., HF, F⁻, or HF²⁻ ions) and the InP surface. Because of the inefficiency of the photoelectrochemical process, the HF-mediated fluorination process is slow with passivation typically requiring hours of illumination, making this process incompatible with high-volume manufacturing (HVM).

The present disclosure provides new wet chemistries, processes and methods for surface passivation of semiconductor materials (e.g., III-V semiconductor materials). In the present disclosure, an electrophilic fluorinating agent (such as Selectfluor™, etc.) is used to fluorinate an exposed surface of a semiconductor material. Unlike HF, electrophilic fluorinating agents react as fluorine cations (F⁺) or fluorine radicals (F^{*}), depending on reaction conditions. These reactants proceed through alternative reaction pathways that passivate the InP surface much faster (e.g., orders of magnitude faster) than the fluorine anions used in HF-mediated surface passivation methods.

In some embodiments, the fluorination process disclosed herein may expose an InP surface to a chemical solution comprising an electrophilic fluorinating agent (such as Selectfluor™, etc.), which reacts with the InP surface to form a fluorinated passivation layer thereon. In some embodiments, the InP surface may be exposed to the chemical solution without illumination in a so-called “dark” fluorination process. Even without illumination, the difference in chemical reactivity between HF and the electrophilic fluorinating agent used in the chemical solution provides significantly faster surface passivation in the dark fluorination process. In some embodiments, the dark fluorination process disclosed herein may form a fluorinated passivation layer on the InP surface orders of magnitude faster than the HF-mediated fluorination process described above. In other embodiments, illumination can be used to further improve the kinetics of surface passivation in a photoactivated fluorination process. In the photoactivated fluorination process, a photosensitive dye is added to the chemical solution to photoactivate the electrophilic fluorinating agent when exposed to illumination, resulting in another order of magnitude improvement in the surface passivation rate.

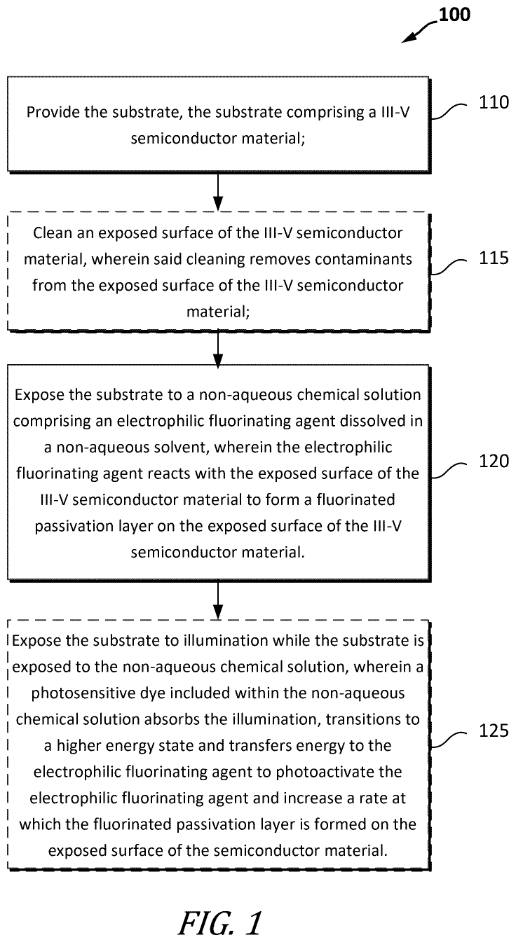

Turning now to the Drawings, FIG. 1 illustrates one embodiment of a method 100 that utilizes the techniques disclosed herein to passivate an exposed surface of a III-V semiconductor material. It will be recognized that the method 100 is merely exemplary and additional methods may utilize the techniques disclosed herein. Further, additional processing steps may be added to the method 100 as the steps described are not intended to be exclusive. Moreover, the order of the steps is not limited to the order shown in the figures as different orders may occur and/or various steps may be performed in combination or at the same time.

The method 100 shown in FIG. 1 begins by providing a substrate comprising a III-V semiconductor material (in step 110). The substrate provided in step 110 may include a wide variety of binary, tertiary and quaternary III-V semiconductor materials. In some embodiments of the method 100, the substrate provided in step 110 may comprise a III-V semiconductor material containing a phosphide or an arsenide. In one example embodiment, the substrate may comprise indium phosphide (InP) having an InP surface.

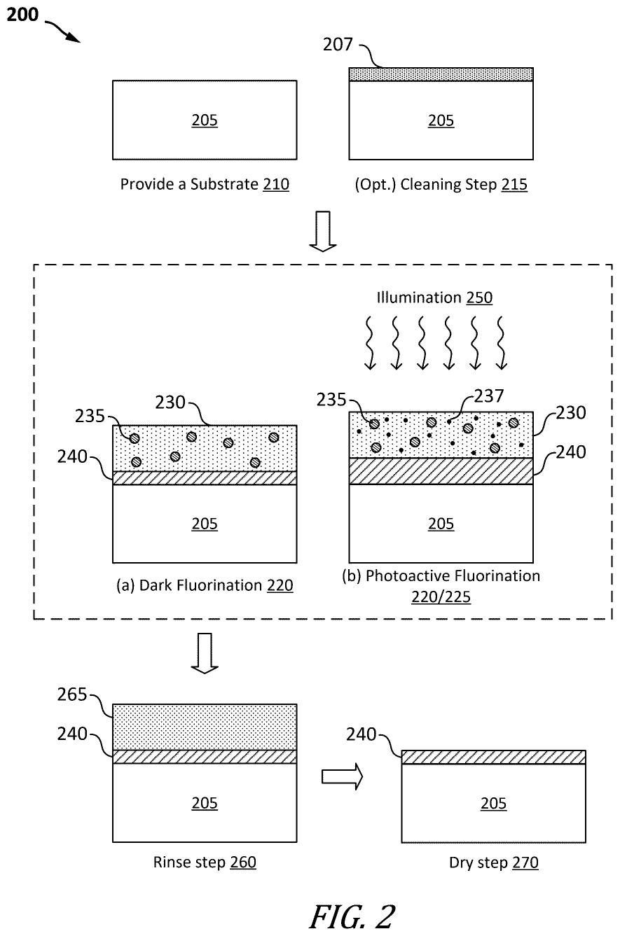

The method 100 further includes exposing the substrate to a non-aqueous chemical solution comprising an electrophilic fluorinating agent dissolved in a non-aqueous solvent (in step 120). A wide variety of electrophilic fluorinating agents and non-aqueous solvents can be included within the non-aqueous chemical solution. In one example embodiment, the non-aqueous chemical solution may include Selectfluor™ dissolved in acetonitrile. Additional examples of electrophilic fluorinating agents and non-aqueous solvents are discussed in more detail below in reference to FIG. 2.

When the substrate is exposed to the non-aqueous chemical solution (in step 120), the electrophilic fluorinating agent reacts with an exposed surface of the III-V semiconductor material to form a fluorinated passivation layer on the exposed surface of the III-V semiconductor material. In some embodiments, an optional cleaning step may be performed (in step 115) to remove any contaminants (e.g., oxidation products or other surface contamination) that may be formed on the exposed surface of the III-V semiconductor material before the substrate is exposed to the non-aqueous chemical solution (in step 120). A wide variety of cleaning processes may be used to remove contaminants from the exposed surface of the III-V semiconductor material. One example of a cleaning process is described in more detail below in reference to FIG. 2.

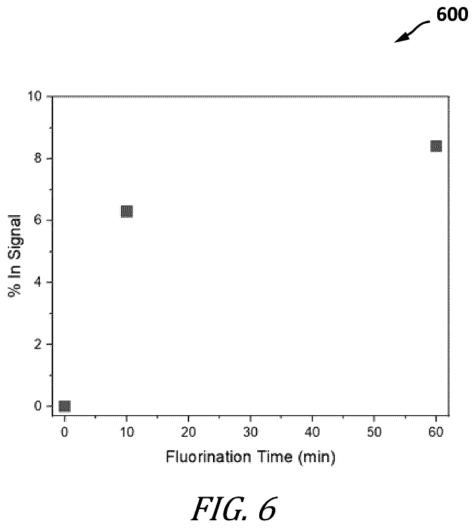

In some embodiments, the III-V semiconductor material may be indium phosphide (InP) having an exposed InP surface. When an InP surface is exposed to the chemical solution (in step 120), the electrophilic fluorinating agent within the chemical solution reacts with the InP surface to form an indium fluoride (InFₓ) passivation layer on the InP surface. As described in more detail below, the fluorination of the InP surface may generally increase over time in a quasi-self-limiting manner (see, e.g., FIG. 6). However, the rate of fluorination (or the surface passivation rate) of the InP surface may be significantly faster (e.g., at least an order of magnitude faster) than the HF-mediated surface passivation method described above.

For example, an indium fluoride (InFₓ) passivation layer may be formed on the InP surface (in step 120) after soaking the substrate in a non-aqueous chemical solution comprising an electrophilic fluorinating agent for less than one hour. In some embodiments, an InFx passivation layer may be formed on the InP surface after approximately 20-40 minutes of soaking in the non-aqueous chemical solution. This relatively fast surface fluorination technique provides a significant improvement (e.g., an order of magnitude improvement) over known InP surface passivation methods, rendering the method 100 shown in FIG. 1 suitable for high volume manufacturing (HVM).

In some embodiments, an optional photoactivation step may be performed (in step 125), while the substrate is exposed to the non-aqueous chemical solution (in step 120), to further improve the kinetics of passivation and increase the surface passivation rate. For example, a photosensitive dye may be added to the non-aqueous chemical solution to photoactivate the electrophilic fluorinating agent contained therein. A wide variety of photosensitive dyes (or photosensitizers) may be added to the non-aqueous chemical solution. In one embodiment, methylene blue (C₁₆H₁₈ClN₃S) may be added to a chemical solution comprising Selectfluor™. In addition to methylene blue, other type I photosensitive dyes may also be added to the chemical solution. However, the photosensitive dye must be chemically stable within the non-aqueous chemical solution and compatible with the electrophilic fluorinating agent. Examples photosensitive dyes that can be used within the non-aqueous chemical solution are discussed in more detail below in reference to FIG. 2.

When a photosensitive dye is added to the non-aqueous chemical solution and the substrate is exposed to illumination (in step 125), the photosensitive dye absorbs the illumination, transitions to a higher energy state and transfers energy to the electrophilic fluorinating agent through a triplet-triplet energy transfer (TTET) process. This energy transfer photoactivates the electrophilic fluorinating agent and increases the rate at which the fluorinated passivation layer is formed on the exposed surface of the III-V semiconductor material. To increase absorption, a center wavelength of the illumination may be well matched to the absorption peak of the photosensitive dye. For example, when methylene blue is added to the chemical solution, the illumination may have an output wavelength centered around for example 655 nm, which is well matched to the broad absorption peak of methylene blue at 665 nm.

Similar to the “dark” fluorination process described above, fluorination of an InP surface using a photoactivated fluorination process may increase over time in a quasi-self-limiting manner (see, e.g., FIG. 8). In some embodiments, the rate of fluorination (or the surface passivation rate) of the InP surface using the photoactivated fluorination process may be even faster (e.g., an order of magnitude faster) than the dark fluorination process described above. For example, an indium fluoride (InFₓ) passivation layer may be formed on the InP surface (in steps 120 and 125) after soaking the substrate in a non-aqueous chemical solution comprising an electrophilic fluorinating agent and a photosensitive dye for less than 35 minutes under illumination. In some embodiments, it may take as little as 90 seconds for an InFx passivation layer to initially be formed on the InP surface using the photoactivated fluorination process disclosed herein. This is two orders of magnitude than the HF-mediated surface passivation method described above. In some cases, the concentration of the photosensitive dye, the electrophilic fluorinating agent and/or the thickness of the chemical solution on the InP surface can be optimized to further increase the kinetics of fluorination.

FIG. 2 illustrates one embodiment of a process flow 200 that utilizes the surface passivation techniques disclosed herein. Like the method 100 shown in FIG. 1, the process flow 200 shown in FIG. 2 may begin by providing a substrate 205 comprising a III-V semiconductor material (in step 210). The substrate 205 provided in step 210 may include a wide variety of binary, tertiary and quaternary III-V semiconductor materials. In some embodiments, the III-V semiconductor material may contain a phosphide, an arsenide or an antimonide. For example, the III-V semiconductor material may be indium phosphide (InP), aluminum phosphide (AlP), gallium phosphide (GaP), aluminum gallium phosphide (AlGaP), gallium indium phosphide (GaInP), aluminum indium phosphide (AlInP), aluminum gallium indium phosphide (AlGaInP), gallium arsenide (GaAs), indium arsenide (InAs), aluminum arsenide (AlAs), indium gallium arsenide (InGaAs), aluminum gallium arsenide (AlGaAs), aluminum indium arsenide (AlInAs), indium antimonide (InSb), aluminum antimonide (AlSb), gallium antimonide (GaSb), indium gallium aluminum antimonide (InGaAlSb), indium gallium antimonide (InGaSb), indium aluminum antimonide (InAlSb), or gallium aluminum antimonide (GaAlSb). In one example embodiment, the substrate 205 provided in step 210 may comprise indium phosphide (InP) having an InP surface.

Similar to the method 100 shown in FIG. 1, the process flow 200 uses an electrophilic fluorinating agent to fluorinate an exposed surface of the III-V semiconductor material and form a fluorinated passivation layer on the exposed surface of the III-V semiconductor material during a surface fluorination process. In some embodiments, the substrate 205 may be exposed to a non-aqueous chemical solution 230 comprising an electrophilic fluorinating agent 235 dissolved in a non-aqueous solvent in the absence of illumination in a dark fluorination process (in step 220). When exposed to the chemical solution 230, the electrophilic fluorinating agent 235 reacts with the exposed surface of the III-V semiconductor material to form a fluorinated passivation layer 240 thereon. In other embodiments, the substrate 205 may be exposed to a non-aqueous chemical solution 230 comprising an electrophilic fluorinating agent 235 and a photosensitive dye 237 in the presence of illumination 250 in a photoactive fluorination process (in steps 220 and 225). When exposed to the chemical solution 230 in the presence of illumination 250, the photosensitive dye 237 absorbs photons from the illumination 250, transitions to a higher energy state and transfers energy to the electrophilic fluorinating agent 235 to photoactivate the electrophilic fluorinating agent 235 (e.g., through a TTET process) and increase the rate at which the fluorinated passivation layer 240 is formed on the exposed surface of the III-V semiconductor material. After surface fluorination, the substrate 205 comprising the fluorinated passivation layer 240 can be rinsed with a solvent 265 (in step 260) and dried (in step 270) with, for example, compressed air.

The extent of fluorination (and thus, the thickness of the fluorinated passivation layer 240) may generally increase over time in a quasi-self-limiting manner in both the dark fluorination process and the photoactive fluorination process described above. However, photoactivation increases the rate of fluorination (or the surface passivation rate) compared to the dark fluorination process. By increasing the rate of fluorination, the photoactive fluorination process may increase the thickness of the fluorinated passivation layer 240 formed on the surface, as shown in FIG. 2, or decrease the time needed to fluorinate the surface. In some embodiments, the photoactive fluorination process may reduce the time needed to form a fluorinated passivation layer 240 of suitable thickness on the surface by approximately 90% of the dark fluorination reaction time.

A wide variety of electrophilic fluorinating agents 235 and non-aqueous solvents can be used in the non-aqueous chemical solution 230 to form the fluorinated passivation layer 240 in the above-described fluorination processes. Examples of electrophilic fluorinating agents 235 include, but are not limited to, Selectfluor™ (1-chloromethyl-4-fluoro-1,4-diazoniabicyclo[2.2.2]octane bis(tetrafluoroborate)), 1-fluoropyridinium triflate, 1-fluoro-2,4,6-trimethylpyridinium tetrafluoroborate, N-fluorobenzenesulfonimide, fluoroxytrifluoromethane, perchloryl fluoride, xenon difluoride and N-fluorobis[(trifluoromethyl)sulfonyl]imide. The non-aqueous solvent used in the chemical solution 230 may generally be an ether, a ketone, a halocarbon, a heterocyclic, an alcohol or another polar organic solvent or chlorocarbon solvent. For example, the non-aqueous solvent may be acetonitrile, ethyl acetate, acetone, dimethyl sulfoxide (DMSO), furan, dimethylformamide, methanol, diethyl ether, isopropyl alcohol, dioxane or toluene. In one example embodiment, the non-aqueous chemical solution 230 may contain Selectfluor™ dissolved in acetonitrile or another non-aqueous solvent. Unlike other electrophilic fluorinating agents, Selectfluor™ is also soluble in water. Thus, in some embodiments, a chemical solution containing Selectfluor™ dissolved in water may be used to form the fluorinated passivation layer 240 on the exposed surface of the III-V semiconductor material.

A wide variety of photosensitive dyes 237 can added to the chemical solution to photoactivate the electrophilic fluorinating agent 235 contained therein. As noted above, the photosensitive dye 237 may be a type I photosensitive dye. Examples of type I photosensitive dyes include, but are not limited to, thiazine dyes (such as, e.g., methylene blue (C₁₆H₁₈ClN₃S)), fluorescein dyes (such as, e.g., Rose Bengal (4,5,6,7-tetrachloro-2′,4′,5′,7′-tetraiodofluorescein)), porphyrin dyes (such as, e.g., porphyrin, substituted porphyrin, and porphyrin-metal complexes), eosin dyes, rhodamine dyes, ruthenium dyes and other metal bipyridines. As noted above, however, the photosensitive dye 237 used within the chemical solution must be compatible with the electrophilic fluorinating agent 235 contained therein. In one embodiment, methylene blue (C₁₆H₁₈ClN₃S) may be added to an aqueous or non-aqueous chemical solution comprising Selectfluor™.

In some embodiments, an optional cleaning step may be performed (in step 215) before the substrate 205 is exposed to the non-aqueous chemical solution 230 (in step 220) to remove any contaminants (e.g., oxidation products or other surface contamination) that may reside on the exposed surface of the III-V semiconductor material. For example, a three step cleaning process can be used to clean an InP surface enough for epitaxial growth. During the three step cleaning process, the substrate 205 may be soaked in a dilute sulfuric acid (H₂SO₄) and hydrogen peroxide (H₂O₂) solution (e.g., a 4:1:100 mixture of H₂SO₄:H₂O₂:H₂O) followed by another soak in an aqueous hydrochloric acid (HCl) solution (e.g., 3:1 mixture of HCl:H₂O). Lastly, the substrate 205 may be annealed to a relatively high temperature (e.g., 330 °C) to complete the cleaning process. Once clean, the InP surface can be fluorinated in steps 220 and/or 225 to form a lasting surface passivation layer. While an example cleaning process is provided for cleaning InP surfaces, one skilled in the art will recognize that other cleaning processes may be used (in step 215) to clean other semiconductor materials.

The method 100 shown in FIG. 1 and the process flow 200 shown in FIG. 2 provide improved techniques for passivating a surface of a III-V semiconductor material formed on and/or within a substrate 205. In examples provided above, an indium phosphide (InP) surface is passivated by exposing the substrate 205 to a chemical solution 230 comprising an electrophilic fluorinating agent 235, which reacts with the InP surface to form a fluorinated passivation layer 240 on the InP surface in a relatively fast, quasi-self-limiting manner. In some embodiments, a photosensitive dye 237 is added to the chemical solution 230 and the substrate 205 is illuminated, while exposed to the chemical solution 230, to further improve the surface passivation rate.

Conventional surface passivation methods for indium phosphide include cladding (with, e.g., zinc sulfide (ZnS) and/or zinc selenide (ZnSe) shells) and surface fluorination with hydrofluoric acid (HF) based chemistries. Unlike conventional InP surface passivation methods, the surface passivation techniques disclosed herein do not deposit semiconductor material (such as ZnS and/or ZnSe) onto the InP surface or expose the InP surface to HF. Instead, the disclosed surface passivating techniques utilize electrophilic fluorinating agents (such as Selectfluor™, etc.) with and without illumination 250 to fluorinate the InP surface and form a quasi-self-limiting fluorinated passivation layer 240. Even without the illumination 250, the difference in chemical reactivity between HF and the electrophilic fluorinating agent used in the chemical solution 230 provides significantly faster surface passivation (e.g., an order of magnitude faster) than the HF-mediated fluorination process. In some embodiments, a photosensitive dye 237 may be added to the chemical solution 230 and the substrate 205 may be exposed to illumination 250 to photoactivate the electrophilic fluorinating agent 235 and further improve the kinetics of passivation, resulting in another order of magnitude improvement in the surface passivation rate.

While specifically described herein for indium phosphide (InP), the disclosed surface passivation techniques can also be used to fluorinate other III-V semiconductor materials containing phosphides, arsenides or antimonides. For example, the disclosed surface passivation techniques can be used to fluorinate a wide variety of binary, tertiary and quaternary III-V semiconductor materials, such as aluminum phosphide (AlP), gallium phosphide (GaP), aluminum gallium phosphide (AlGaP), gallium indium phosphide (GaInP), aluminum indium phosphide (AlInP), aluminum gallium indium phosphide (AlGaInP), gallium arsenide (GaAs), indium arsenide (InAs), aluminum arsenide (AlAs), indium gallium arsenide (InGaAs), aluminum gallium arsenide (AlGaAs), aluminum indium arsenide (AlInAs), indium antimonide (InSb), aluminum antimonide (AlSb), gallium antimonide (GaSb), indium gallium aluminum antimonide (InGaAlSb), indium gallium antimonide (InGaSb), indium aluminum antimonide (InAlSb) and gallium aluminum antimonide (GaAlSb).

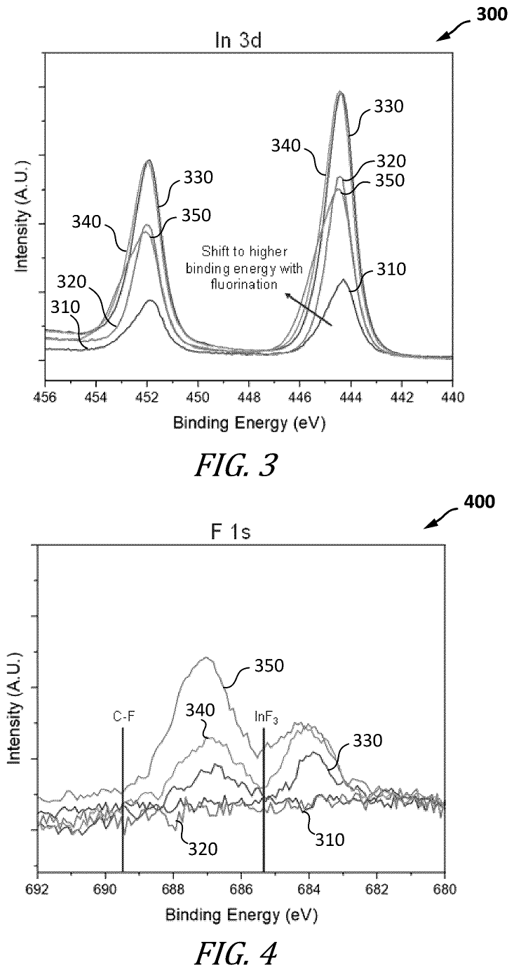

Experiments were conducted on 15 mm×15 mm coupons cut from a 50 mm indium phosphide substrate to investigate the surface passivation techniques shown in FIGS. 1 and 2. Before conducting the experiments, InP coupons were cleaned using the three step cleaning process described above. In a first experiment, clean InP coupons were dipped in a chemical solution containing 1% Selectfluor™ in acetonitrile for various times (e.g., 10 minutes and 60 minutes) and then rinsed with acetonitrile. In a second experiment, a chemical solution containing 1% Selectfluor™ and micromolar amounts of methylene blue in acetonitrile was dispensed onto another clean InP coupon and an LED array having an output wavelength centered at 655 nm was used to illuminate the solution covered InP coupon for 1 minute. After 1 minute, the LED array was turned off and the solution covered InP coupon was rinsed with acetonitrile and dried. The illumination time was limited in the second experiment to 1 minute to minimize photobleaching and solvent evaporation. The process of dispensing the chemical solution onto the InP coupon and illuminating the solution covered InP coupon for 1 minute, followed by rinsing and drying was then repeated as necessary to achieve a desired fluorination time (e.g., 1 minute, 5 minutes, 10 minutes, 25 minutes, etc.). After fluorination, X-ray photoelectron spectroscopy (XPS) analysis was performed to investigate the surface composition of the InP coupons as-deposited, after cleaning and after fluorination using the various fluorination techniques described herein. Results of the XPS analysis are shown in FIGS. 3-8.

The graph 300 shown in FIG. 3 illustrates the XPS data obtained for the indium (In) 3d spectra of InP coupons as received (“As received”, line 310), after cleaning (“Cleaned”, line 320), after fluorination for 10 minutes (“10 min Selectfluor”, line 330) and 60 minutes (“60 min Selectfluor”, line 340) using the dark fluorination process described herein, and after fluorination for 10 minutes (“10 min TTET”, line 350) using the photoactivated fluorination process described herein. As shown in the graph 300, a high binding energy peak appears on fluorination regardless of fluorination technique. The intensity of the high binding energy peak increases with fluorination time (e.g., 10 minutes to 60 minutes). The presence of illumination (line 350) increases the intensity of the high binding energy peak when compared to dark fluorination for the same time.

The graph 400 shown in FIG. 4 illustrates the XPS data obtained for the fluorine (F) 1s spectra of InP coupons as received (“As received”, line 310), after cleaning (“Cleaned”, line 320), after fluorination for 10 minutes (“10 min Selectfluor”, line 330) and 60 minutes (“60 min Selectfluor”, line 340) using the dark fluorination process described herein, and after fluorination for 10 minutes (“10 min TTET”, line 350) using the photoactivated fluorination process described herein. As shown in the graph 400, no fluorine is detectable on the as received (line 310) and cleaned (line 320) samples, as expected. However, peaks with two distinct binding energies are seen in the InP coupons fluorinated for 10 minutes without illumination (line 330), 60 minutes without illumination (line 340) and 10 minutes with illumination (line 350). The binding energy of the two F 1s peaks are inconsistent with bulk indium trifluoride (InF₃), but the lower binding energy peak at 684 eV is in good agreement with results seen in the literature for the non-aqueous HF-mediated surface passivation process. The higher binding energy peak at 687 eV is consistent with P-F bonds (686 eV). In the graph 400, the intensity of both the lower and the higher binding energy peaks increases with fluorination time (e.g., 10 minutes to 60 minutes) and with illumination.

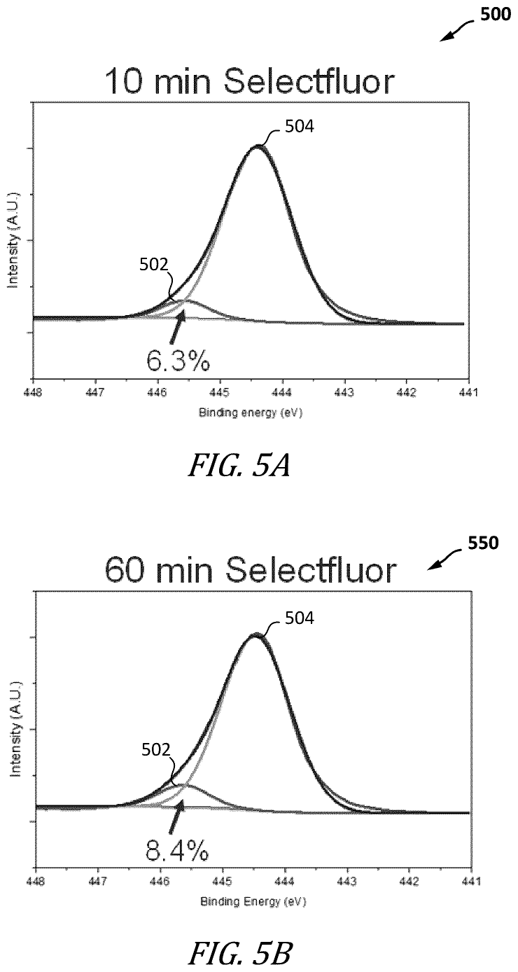

The extent of fluorination was tracked as a function fluorination time for the dark fluorination process described herein. The graphs 500 and 550 shown in FIGS. 5A-5B show the deconvolution of the In 3d_{5/2} peak after 10 minutes and 60 minutes of fluorination with the Selectfluor™ solution described above in the absence of illumination. As shown in the graphs 500 and 550, the dark fluorination process disclosed herein results in a lower binding energy peak (“Peak 2”, line 504) consistent with InP and a higher binding energy peak (“Peak 1”, line 502) consistent with indium fluoride (InFₓ). The fractional integrated area of the higher binding energy peak (“Peak 1”) increases over time from approximately 6.3% after 10 minutes of fluorination without illumination (graph 500) to approximately 8.4% after 60 minutes without illumination (graph 550).

The graph 600 shown in FIG. 6 plots the fractional integrated area of the higher binding energy peak (“Peak 1”) as a function of fluorination time (expressed in minutes) as a metric for the extent of fluorination achieved using the dark fluorination process described herein. As shown in the graph 600, fluorination increases over time in a quasi-self-limiting manner.

As known in the art, a “self-limiting reaction” is a chemical reaction that inherently stops once a specific condition is met (such as, for example, when a reactant is used up, the reactive sites on a surface are entirely depleted or an inert passivation layer is formed on the surface). Thus, in a purely self-limiting reaction, the reaction rate decreases over time and eventually goes to zero. In contrast, the reaction rate in a “quasi-self-limiting reaction” slows down over time but never reaches zero. As shown in the graph 600, the fluorination rate increases sharply between 0-10 minutes, but decreases significantly between 10-60 minutes of fluorination time without going to zero, resulting in quasi-self-limiting behavior during the time frames investigated for the experiments.

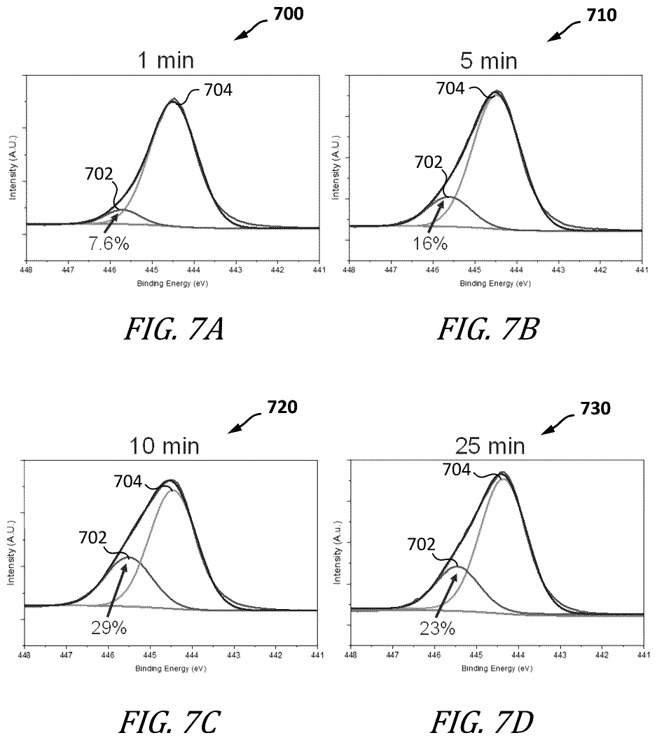

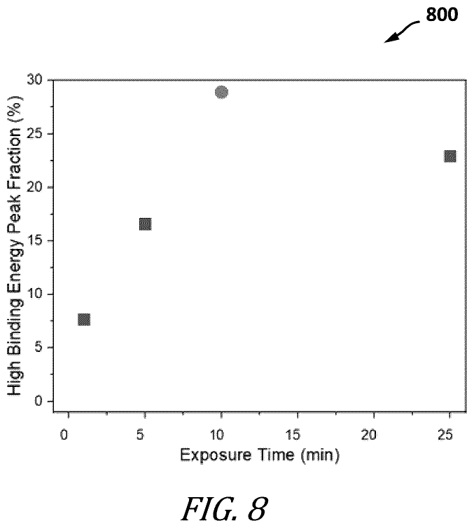

The extent of fluorination was also tracked as a function fluorination time for the photoactivated fluorination process described herein. The graphs 700, 710, 720 and 730 shown in FIGS. 7A-7D show the deconvolution of the In 3d_{5/2} peak after 1 minute, 5 minutes, 10 minutes and 25 minutes of fluorination with the Selectfluor™ and methylene blue solution described above in the presence of illumination. As shown in the graphs 700, 710, 720 and 730, the photoactive fluorination process disclosed herein results in a lower binding energy peak (“Peak 2”, line 704) consistent with InP and a higher binding energy peak (“Peak 1”, line 702) consistent with indium fluoride (InFₓ). Compared to the dark fluorination process, the photoactivated fluorination process led to a larger high binding energy peak in the In 3d spectra and a larger integrated area in the F 1s spectra. In the photoactivated fluorination process, the fractional integrated area of the higher binding energy peak (“Peak 1”, line 702) generally increased over time from approximately 7.6% after 1 minute of fluorination (graph 700) to: (a) approximately 16% after 5 minutes of fluorination (graph 710), (b) approximately 29% after 10 minutes of fluorination (graph 702), and (c) approximately 23% after 25 minutes of fluorination (graph 730). The data for the 10 min experiment was collected as part of a different set of coupons sent for analysis, so differences in the delays between fluorination and analysis may be responsible for apparent disagreement in the fluorination kinetics. In either case, the photoactivated fluorination process results in both faster fluorination kinetics and a higher extent of fluorination compared to the dark fluorination process.

The graph 800 shown in FIG. 8 plots the fractional integrated area of the higher binding energy peak (“Peak 1”) as a function of fluorination time (expressed in minutes) as a metric for the extent of fluorination achieved using the photoactivated fluorination process described herein. As shown in the graph 800, fluorination increases over time in a quasi-self-limiting manner.

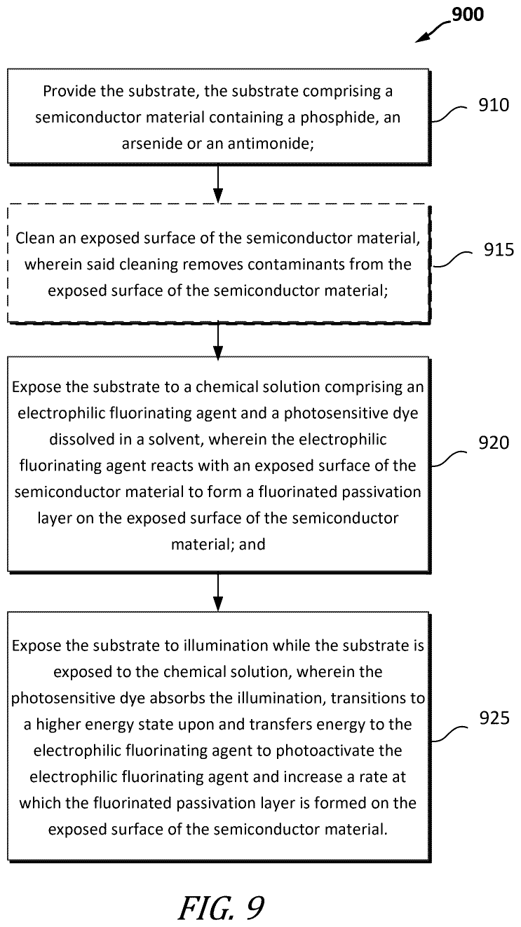

FIG. 9 illustrates one embodiment of a method 900 that utilizes the techniques disclosed herein to passivate an exposed surface of a semiconductor material. It will be recognized that the method 900 is merely exemplary and additional methods may utilize the techniques disclosed herein. Further, additional processing steps may be added to the method 900 as the steps described are not intended to be exclusive. Moreover, the order of the steps is not limited to the order shown in the figures as different orders may occur and/or various steps may be performed in combination or at the same time.

The method 900 shown in FIG. 9 begins by providing a substrate comprising a semiconductor material containing a phosphide, an arsenide or an antimonide (in step 910). The substrate provided in step 910 may include a wide variety of binary, tertiary and quaternary III-V semiconductor materials. In some embodiments of the method 900, the substrate provided in step 910 may comprise a III-V semiconductor material containing a phosphide, an arsenide or an antimonide. Examples of III-V semiconductor materials containing phosphides, arsenides and antimonides are mentioned above. In one example embodiment, the substrate may comprise indium phosphide (InP) having an InP surface.

The method 900 shown in FIG. 9 further includes exposing the substrate to a chemical solution comprising an electrophilic fluorinating agent and a photosensitive dye dissolved in a solvent (in step 920) and exposing the substrate to illumination while the substrate is exposed to the chemical solution (in step 925). When exposed to the chemical solution (in step 920), the electrophilic fluorinating agent reacts with an exposed surface of the semiconductor material to form a fluorinated passivation layer on the exposed surface of the semiconductor material. When exposed to the chemical solution in the presence of illumination (in step 925), the photosensitive dye absorbs the illumination, transitions to a higher energy state and transfers energy to the electrophilic fluorinating agent to photoactivate the electrophilic fluorinating agent and increase a rate at which the fluorinated passivation layer is formed on the exposed surface of the semiconductor material. In some embodiments, the method 900 may clean the exposed surface of the semiconductor material to remove contaminants there from (in optional step 915) prior to exposing the substrate to the chemical solution (in step 920).

A wide variety of electrophilic fluorinating agents, photosensitive dyes and solvents can be used in the non-aqueous chemical solution to form the fluorinated passivation layer in the method 900. Examples of electrophilic fluorinating agents, photosensitive dyes and aqueous and non-aqueous solvents are discussed above in reference to FIGS. 1 and 2. In one example embodiment, the semiconductor material may be indium phosphide (InP) having an InP surface, and chemical solution may contain Selectfluor™ and methylene blue dissolved in acetonitrile.

Methods for processing a substrate are described in various embodiments. More specifically, embodiments of methods for passivating a semiconductor material (e.g., a III-V semiconductor material) formed on and/or within a substrate are described herein. The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for processing a substrate, comprising:
providing the substrate, the substrate comprising a III-V semiconductor material; and
exposing the substrate to a non-aqueous chemical solution comprising an electrophilic fluorinating agent dissolved in a non-aqueous solvent, wherein the electrophilic fluorinating agent reacts with an exposed surface of the III-V semiconductor material to form a fluorinated passivation layer on the exposed surface of the III-V semiconductor material.

2. The method of claim 1, wherein prior to exposing the substrate to the non-aqueous chemical solution, the method further comprises:
cleaning the exposed surface of the III-V semiconductor material, wherein said cleaning removes contaminants from the exposed surface of the III-V semiconductor material.

3. The method of claim 1, wherein the non-aqueous chemical solution further comprises a photosensitive dye, and wherein the method further comprises:
exposing the substrate to illumination while the substrate is exposed to the non-aqueous chemical solution, wherein the photosensitive dye absorbs the illumination, transitions to a higher energy state and transfers energy to the electrophilic fluorinating agent to photoactivate the electrophilic fluorinating agent and increase a rate at which the fluorinated passivation layer is formed on the exposed surface of the III-V semiconductor material.

4. The method of claim 1, wherein the III-V semiconductor material comprises indium phosphide (InP) having an InP surface, and wherein the electrophilic fluorinating agent reacts with the InP surface to form an indium fluoride (InFₓ) passivation layer on the InP surface.

5. The method of claim 4, wherein the non-aqueous chemical solution does not contain hydrofluoric acid (HF).

6. The method of claim 4, wherein the electrophilic fluorinating agent is Selectfluor™ (1-chloromethyl-4-fluoro-1,4-diazoniabicyclo[2.2.2]octane bis(tetrafluoroborate)), 1-fluoropyridinium triflate, 1-fluoro-2,4,6-trimethylpyridinium tetrafluoroborate, N-fluorobenzenesulfonimide, fluoroxytrifluoromethane, perchloryl fluoride, xenon difluoride or N-fluorobis[(trifluoromethyl)sulfonyl]imide, and wherein the non-aqueous solvent is an ether, a ketone, a halocarbon, a heterocyclic, an alcohol or another polar organic solvent or chlorocarbon solvent.

7. The method of claim 4, wherein the electrophilic fluorinating agent is Selectfluor™ (1-chloromethyl-4-fluoro-1,4-diazoniabicyclo[2.2.2]octane bis(tetrafluoroborate)), and wherein the non-aqueous solvent is acetonitrile, ethyl acetate, acetone, dimethyl sulfoxide (DMSO), furan, dimethylformamide, methanol, diethyl ether, isopropyl alcohol, dioxane or toluene.

8. The method of claim 4, wherein the non-aqueous chemical solution further comprises a photosensitive dye, and wherein the method further comprises:
exposing the substrate to illumination while the substrate is exposed to the non-aqueous chemical solution, wherein the photosensitive dye absorbs the illumination, transitions to a higher energy state and transfers energy to the electrophilic fluorinating agent to photoactivate the electrophilic fluorinating agent and increase a rate at which the indium fluoride (InFₓ) passivation layer is formed on the InP surface.

9. The method of claim 8, wherein prior to exposing the substrate to the non-aqueous chemical solution, the method further comprises:
selecting the photosensitive dye for use within the non-aqueous chemical solution, wherein the photosensitive dye selected for use is chemically stable within the non-aqueous chemical solution.

10. The method of claim 9, wherein the photosensitive dye comprises a thiazine dye, a fluorescein dye, a porphyrin dye, an eosin dye, a rhodamine dye, a ruthenium dye or another metal bipyridine.

11. The method of claim 9, wherein the non-aqueous chemical solution comprises Selectfluor™ and methylene blue (C₁₆H₁₈ClN₃S) dissolved in acetonitrile.

12. A method for processing a substrate, comprising:
providing the substrate, the substrate comprising a semiconductor material containing a phosphide, an arsenide or an antimonide;
exposing the substrate to a chemical solution comprising an electrophilic fluorinating agent and a photosensitive dye dissolved in a solvent, wherein the electrophilic fluorinating agent reacts with an exposed surface of the semiconductor material to form a fluorinated passivation layer on the exposed surface of the semiconductor material; and
exposing the substrate to illumination while the substrate is exposed to the chemical solution, wherein the photosensitive dye absorbs the illumination, transitions to a higher energy state and transfers energy to the electrophilic fluorinating agent to photoactivate the electrophilic fluorinating agent and increase a rate at which the fluorinated passivation layer is formed on the exposed surface of the semiconductor material.

13. The method of claim 12, wherein prior to exposing the substrate to the chemical solution, the method further comprises:
cleaning the exposed surface of the semiconductor material, wherein said cleaning removes contaminants from the exposed surface of the semiconductor material.

14. The method of claim 12, wherein the semiconductor material is indium phosphide (InP), aluminum phosphide (AlP), gallium phosphide (GaP), aluminum gallium phosphide (AlGaP), gallium indium phosphide (GaInP), aluminum indium phosphide (AlInP), aluminum gallium indium phosphide (AlGaInP), gallium arsenide (GaAs), indium arsenide (InAs), aluminum arsenide (AlAs), indium gallium arsenide (InGaAs), aluminum gallium arsenide (AlGaAs), aluminum indium arsenide (AlInAs), indium antimonide (InSb), aluminum antimonide (AlSb), gallium antimonide (GaSb), indium gallium aluminum antimonide (InGaAlSb), indium gallium antimonide (InGaSb), indium aluminum antimonide (InAlSb), or gallium aluminum antimonide (GaAlSb).

15. The method of claim 12, wherein the semiconductor material is indium phosphide (InP) having an InP surface, and wherein the electrophilic fluorinating agent reacts with the InP surface to form an indium fluoride (InFₓ) passivation layer on the InP surface.

16. The method of claim 15, wherein the chemical solution does not contain hydrofluoric acid (HF).

17. The method of claim 12, wherein the electrophilic fluorinating agent is Selectfluor™ (1-chloromethyl-4-fluoro-1,4-diazoniabicyclo[2.2.2]octane bis(tetrafluoroborate)), 1-fluoropyridinium triflate, 1-fluoro-2,4,6-trimethylpyridinium tetrafluoroborate, N-fluorobenzenesulfonimide, fluoroxytrifluoromethane, perchloryl fluoride, xenon difluoride or N-fluorobis[(trifluoromethyl)sulfonyl]imide, and wherein the solvent is water, an ether, a ketone, a halocarbon, a heterocyclic, an alcohol or another polar organic solvent or chlorocarbon solvent.

18. The method of claim 12, wherein the electrophilic fluorinating agent is Selectfluor™ (1-chloromethyl-4-fluoro-1,4-diazoniabicyclo[2.2.2]octane bis(tetrafluoroborate)), and wherein the solvent is water, acetonitrile, ethyl acetate, acetone, dimethyl sulfoxide (DMSO), furan, dimethylformamide, methanol, diethyl ether, isopropyl alcohol, dioxane or toluene.

19. The method of claim 12, wherein the photosensitive dye comprises a thiazine dye, a fluorescein dye, a porphyrin dye, an eosin dye, a rhodamine dye, a ruthenium dye or another metal bipyridine.

20. The method of claim 12, wherein the chemical solution comprises Selectfluor™ and methylene blue (C₁₆H₁₈ClN₃S) dissolved in acetonitrile.
